(19) United States
(12) Patent Application Publication
(10) Pub. No.: US 2026/0057952 A1
(43) Pub. Date: Feb. 26, 2026

(54) NON-VOLATILE MEMORY DEVICE CAPABLE OF DETECTING BONDING DEFECTS AND DEFECT DETECTION METHOD THEREOF

(71) Applicant: SAMSUNG ELECTRONICS CO., LTD., Suwon-si (KR)

(72) Inventor: BU-IL NAM, Suwon-si (KR)

(73) Assignee: SAMSUNG ELECTRONICS CO., LTD., Suwon-si (KR)

(21) Appl. No.: 19/065,734

(22) Filed: Feb. 27, 2025

(30) Foreign Application Priority Data
Aug. 23, 2024 (KR) 10-2024-0113207

(51) Int. Cl. G11C 29/12

(52) U.S. Cl. CPC G11C 29/12005; G11C 2029/1202

(57) ABSTRACT

A non-volatile memory device includes a cell array including memory cells connected to a word line; a voltage generator to generate a word line voltage and provide the word line voltage to the word line; a word line bonding electrically connecting the voltage generator and the word line; and a bonding defect detection circuit connected to a first node between the voltage generator and the word line bonding, and to detect a voltage level of the first node in a precharge section or a development section of the word line to determine whether there is a defect in the word line bonding, detect a precharge speed of the word line in the precharge section to identify an open defect or a resistive defect, and detect a discharge speed of the word line that has been precharged in the development section to identify a short defect in the word line bonding.

### CROSS-REFERENCE TO RELATED APPLICATIONS

This application claims priority under 35 U.S.C. § 119 to Korean Patent Application No. 10-2024-0113207 filed on Aug. 23, 2024, in the Korean Intellectual Property Office, the disclosure of which is incorporated by reference herein in its entirety.

### BACKGROUND

The present disclosure relates to a semiconductor device, and more specifically, to a non-volatile memory device capable of detecting bonding defects and a defect detection method thereof.

Non-volatile memory devices can store data even when power is cut off. Volatile memory devices are mainly used as main memory in computers, and non-volatile memory devices are used as large-capacity storage for storing data. Recently, non-volatile memory devices in which memory cells are stacked in three dimensions, such as vertical NAND flash memory devices, have been actively studied in order to improve the integration of semiconductor memory devices. In addition, hybrid bonding technology, which directly bonds a die where a cell array is formed and a die where control logic is formed, is being actively researched in order to implement high-performance and high-density non-volatile memory devices. When NAND flash memory is formed by applying hybrid bonding, performance very close to monolithic design can be provided with almost no power and signal penalties.

However, alignment between dies is an issue in implementing hybrid bonding. Bonding defects can be minimized only when there is no alignment error between chips bonded. Bonding defects can occur due to various factors, but bonding defects can be electrically summarized into three types: open defects, resistive defects, and short defects. However, there is currently no test technology that can detect all of these various types of bonding defects.

### SUMMARY

Embodiments of the present disclosure provide a non-volatile memory device capable of detecting bonding defects by type and a method for detecting bonding defects thereof.

According to an aspect of an embodiment, a non-volatile memory device includes: a cell array including memory cells connected to a word line; a voltage generator configured to generate a word line voltage and provide the word line voltage to the word line; a word line bonding configured to electrically connect the voltage generator and the word line; and a bonding defect detection circuit connected to a first node between the voltage generator and the word line bonding, and configured to detect a voltage level of the first node in a precharge section of the word line or in a development section of the word line to determine whether there is a defect in the word line bonding, wherein the bonding defect detection circuit is further configured to: detect a precharge speed of the word line in the precharge section to identify an open defect or a resistive defect, and detect a discharge speed of the word line that has been precharged in the development section to identify a short defect in the word line bonding.

According to an aspect of an embodiment, a method of detecting bonding defect a non-volatile memory device that transmits a word line voltage generated by a voltage generator to a word line of a cell array through a word line bonding, includes: precharging the word line with the word line voltage; counting a first time when a voltage level of the word line becomes higher than a reference voltage from a time of precharge using a counter to generate a first detection count; and identifying a bonding defect of the word line based on the first detection count, wherein the bonding defect is an open defect or a resistive defect.

According to an aspect of an embodiment, a non-volatile memory device includes: memory cells connected to a word line; a voltage generator configured to generate a word line voltage and provide the word line voltage to the word line; a word line bonding configured to electrically connect the voltage generator and the word line; a voltage drop circuit connected to a first node between the voltage generator and the word line bonding to drop a level of the word line voltage and provide a dropped word line voltage as a detection voltage to a second node; and a bonding defect detection circuit configured to detect a level of the detection voltage in a precharge section of the word line or in a development section of the word line to determine whether the word line bonding is defective, wherein the bonding defect detection circuit is further configured to: detect a precharge speed of the word line in the precharge section based on the level of the detection voltage to identify an open defect or a resistive defect, and detect a discharge speed of the word line that has been precharged in the development section to identify a short defect of the word line bonding.

### BRIEF DESCRIPTION OF THE DRAWINGS

The above and other aspects and features of the present disclosure will become apparent by describing in detail embodiments thereof with reference to the accompanying drawings, in which:

FIG. 1 is a drawing showing a manufacturing process of a non-volatile memory device according to an embodiment;

FIG. 2 is a drawing briefly showing detectable bonding defects in a non-volatile memory device according to an embodiment;

FIG. 3 is a cross-sectional view showing a non-volatile memory device according to an embodiment;

FIG. 4 is a block diagram showing a memory system according to an embodiment;

FIG. 5 is a block diagram showing a non-volatile memory device according to an embodiment;

FIG. 6 is a circuit diagram showing a structure of a memory block constituting the cell array of FIG. 5 according to an embodiment;

FIG. 7 is a block diagram showing a configuration of a bonding defect detector according to an embodiment;

FIG. 8 is a waveform diagram showing a bonding defect test operation of the bonding defect detector of FIG. 7;

FIG. 9 is a flowchart showing a test operation for defect detection performed in the bonding defect detector according to an embodiment;

FIG. 10 is a flowchart showing step S120 of FIG. 9 in more detail;

FIG. 11 is a flowchart showing step S150 of FIG. 9 in more detail;

FIG. 12 is a block diagram showing the bonding defect detector of FIG. 5 according to an embodiment;

FIG. 13A and FIG. 13B are circuit diagrams of a voltage drop circuit of FIG. 12 according to embodiments;

FIG. 14 is a block diagram showing a configuration of the bonding defect detector of FIG. 12 according to an embodiment;

FIG. 15 is a graph showing first and second reference values provided to the comparators of FIG. 14;

FIG. 16 is a waveform diagram showing a bonding defect test operation of the bonding defect detector of FIG. 14; and

FIG. 17 is a block diagram showing a storage system including a non-volatile memory device according to an embodiment.

### DETAILED DESCRIPTION

It is to be understood that both the foregoing general description and the following detailed description are exemplary. Reference signs are indicated in detail in example embodiments, examples of which are indicated in the reference drawings. Wherever possible, the same reference numbers are used in the description and drawings to refer to the same or like parts.

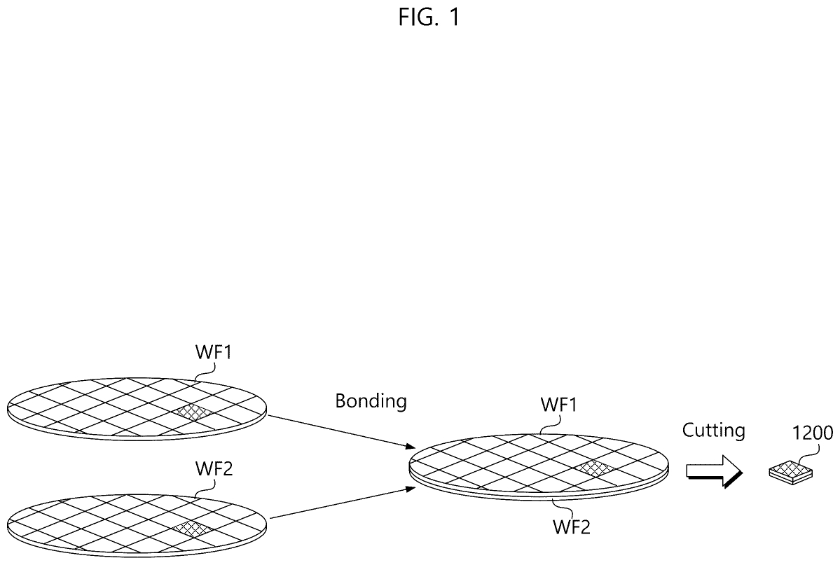

FIG. 1 is a drawing showing a manufacturing process of a non-volatile memory device according to an embodiment. Referring to FIG. 1, a non-volatile memory device 1200 may be formed as a stacked semiconductor memory by applying a wafer bonding method.

Integrated circuits are formed on each of the first wafer WF1 and the second wafer WF2. For example, a memory cell array may be formed on the first wafer WF1, and a peripheral circuit may be formed on the second wafer WF2. The peripheral circuit includes a voltage generator, a page buffer, a decoder, a control circuit, and the like. In particular, the peripheral circuit may include a bonding defect detector BDD, word line switches, and/or block switches.

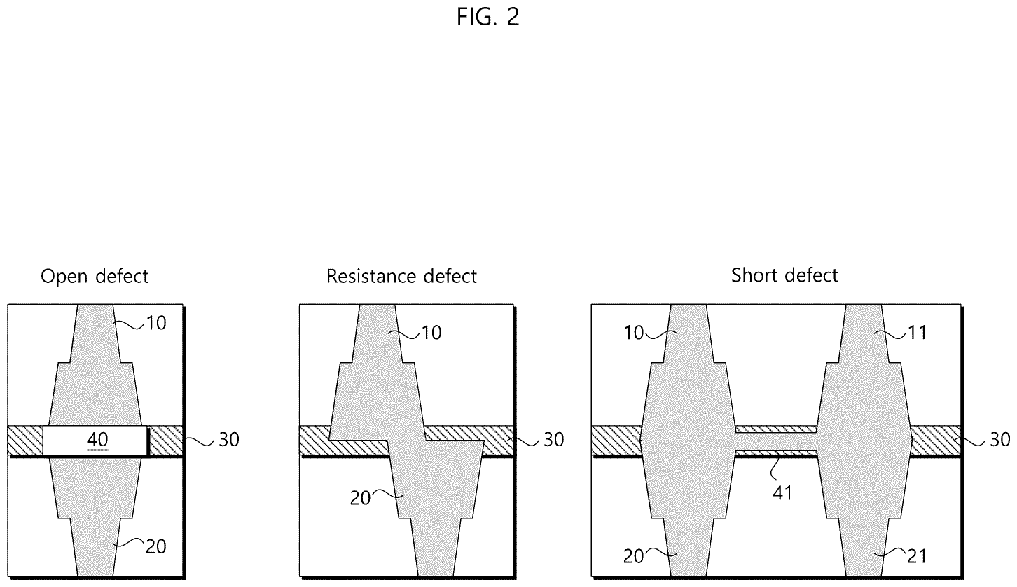

The first wafer WF1 and the second wafer WF2 on which the integrated circuits are formed are bonded using a hybrid bonding method. That is, the metals (e.g., copper) of the first wafer WF1 and the second wafer WF2 are bonded to each other, and the dielectrics (e.g., oxide films) of the first wafer WF1 and the second wafer WF2 are bonded to each other. For bonding, the surfaces of the first wafer WF1 and the second wafer WF2 are processed through a planarization and cleaning process. Then, the dielectrics are bonded by being pressurized under low pressure conditions. See item 30 of FIG. 2. Finally, the metals filled in the upper and lower via holes are bonded through heat treatment.

The wafers WF1 and WF2 that have completed bonding are cut into a plurality of chips. Then, each of the cut chips is provided as a stacked non-volatile memory device 1200 in which upper and lower semiconductor dies are bonded.

The non-volatile memory device 1200 includes the bonding defect detector BDD. The bonding defect detector BDD can detect word line loading characteristics according to the size of bonding resistance during a defect test of a non-volatile memory device 1200. For example, the bonding defect detector BDD can detect a change in the precharge speed or the rising slope of the precharge voltage in the precharge section of the word line. In addition, the bonding defect detector BDD can detect a discharge speed of a precharged word line in the development section of the word line. Due to the characteristics of the bonding defect detector BDD described above, the non-volatile memory device 1200 can detect all of an open defect, a resistive defect, and a short defect.

FIG. 2 is a drawing briefly showing bonding defects that can be detected in the non-volatile memory device. Referring to FIG. 2, bonding defects appearing in the non-volatile memory device 1200 can be broadly expressed as open defects, resistive defects, and short defects.

The open defect indicates a state in which the electrical connection between the upper metal 10 formed on the upper die and the lower metal 20 formed on the lower die is blocked after the bonding process. In other words, air bubble 40 may formed between the upper metal 10 and the lower metal 20. The upper metal 10 and the lower metal 20 may not expand sufficiently during the high temperature annealing process for connecting the upper metal 10 and the lower metal 20. In this case, the upper metal 10 and the lower metal 20 may not adhere and may be electrically blocked.

The resistive defect indicates a state in which the contact area is reduced due to a problem in the alignment of the upper metal 10 and the lower metal 20. That is, a defect in which the bonding resistance Rb increases because the upper metal 10 and the lower metal 20 do not sufficiently contact each other is called the resistive defect. If the resistive defect exists, reliability problems such as generation of heat and a decrease in signal level may occur due to an increase in bonding resistance

The short defect refers to a state in which an electrical short 41 occurs between the bonding (10, 20) formed by the upper metal 10 and the lower metal 20 and the bonding (11, 21) formed by the upper metal 11 and the lower metal 21 adjacent to each other. In this case, when precharging or developing one word line, a problem in signal transmission may occur due to leakage of charges.

The non-volatile memory device 1200 can detect the precharge speed of the word line voltage VWL through a bonding defect detector BDD. In addition, the bonding defect detector BDD can detect the discharge rate of the word line voltage VWL in the development section of the word line. In the precharge section and the development section of the word line, the bonding defect detector BDD can detect all of open defect, resistive defect, and short defect.

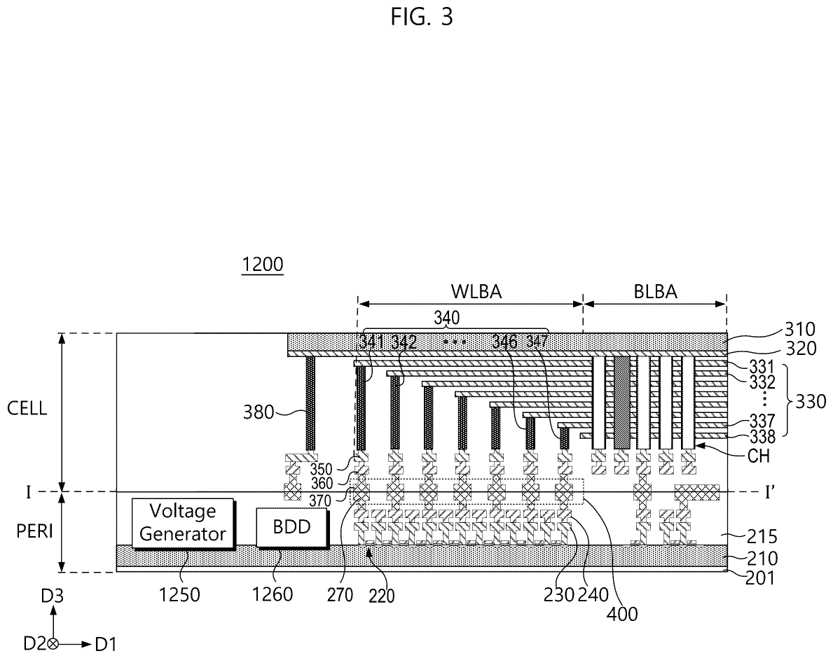

FIG. 3 is a cross-sectional view showing a non-volatile memory device according to an embodiment. Referring to FIG. 3, the non-volatile memory device 1200 may have a chip to chip C2C structure. In order to form the non-volatile memory device 1200 with the C2C structure, an upper chip including a cell region CELL is manufactured on a first wafer, and a lower chip including a peripheral circuit region PERI is manufactured on a second wafer different from the first wafer. Thereafter, the non-volatile memory device 1200 is formed with the C2C structure by bonding the upper chip and the lower chip at the bonding surface (I-I′).

The peripheral circuit region PERI may include a first substrate 210, an interlayer insulating layer 215, a plurality of circuit elements 220 formed on the first substrate 210, a first metal layer 230 connected to each of the plurality of circuit elements 220, and a second metal layer 240 formed on the first metal layer 230. In one embodiment, the first metal layer 230 may be formed of tungsten having a relatively high resistance, and the second metal layer 240 may be formed of copper having a relatively low resistance.

The interlayer insulating layer 215 is disposed on the first substrate 210 to cover the plurality of circuit elements 220, the first metal layer 230, and the second metal layer 240, and may include an insulating material such as silicon oxide, silicon nitride, etc. A lower bonding metal 270 may be formed on the second metal layer 240 of the word line bonding area WLBA. In the word line bonding area WLBA, the lower bonding metal 270 of the peripheral circuit region PERI may be electrically connected to the upper bonding metal 370 of the cell region CELL by a bonding method, and the lower bonding metal 270 and the upper bonding metal 370 may be formed of aluminum, copper, or tungsten.

The cell region CELL may provide at least one memory block. The cell region CELL may include a second substrate 310 and a common source line 320. On the second substrate 310, a plurality of word lines (331, 332, 333, 334, 335, 336, 337, 338; 330) may be laminated along a third direction D3 perpendicular to the upper surface of the second substrate 310.

In a bit line bonding area BLBA, a channel structure CH may extend in a direction perpendicular to the upper surface of the second substrate 310 and penetrate the word lines 330, string selection lines, and ground selection lines. The channel structure CH may include a data storage layer, a channel layer, and a buried insulating layer, and the channel layer may be electrically connected to the first metal layer 350 and the second metal layer 360. For example, the first metal layer 350 may be a bit line contact, and the second metal layer 360 may be a bit line.

In the word line bonding area WLBA, the word lines 330 may extend along a first direction D1 parallel to the upper surface of the second substrate 310 and may be connected to a plurality of cell contact plugs (341, 342, 343, 344, 345, 346, 347; 340). The word lines 330 and the cell contact plugs 340 may be connected to each other at pads provided by extending at least some of the word lines 330 with different lengths along the first direction D1. The first metal layer 350 and the second metal layer 360 may be sequentially connected to the lower portion of the cell contact plugs 340 connected to the word lines 330. The cell contact plugs 340 may be connected to the peripheral circuit region PERI through the upper bonding metal 370 of the cell region CELL in the word line bonding area WLBA and the lower bonding metal 270 of the peripheral circuit region PERI.

The cell contact plugs 340 transmit the word line voltage VWL provided by a voltage generator 1250 of the peripheral circuit region PERI to the word lines 330. The word line voltage VWL generated from the voltage generator 1250 is transmitted to the cell contact plugs 340 and the word line 330 via the lower bonding metal 270 and the upper bonding metal 370 connected to the upper portions of the first metal layer 230 and the second metal layer 240. Here, the bonding that combines the lower bonding metal 270 and the upper bonding metal 370 is referred to as word line bonding 400. The word line bonding 400 for providing the word line voltage VWL to each of the word lines 330 is formed by the lower bonding metals 270 and the upper bonding metals 370.

If a bonding defect occurs between the upper bonding metal 370 and the lower bonding metal 270, normal transmission of the word line voltage VWL is impossible. Therefore, in order to detect the bonding defect of the upper bonding metal 370 and the lower bonding metal 270, the bonding defect detector 1260 is provided. The bonding defect detector 1260 can detect the precharge or development characteristic of each of the word lines 330 to identify the type of bonding defect. For example, if the precharge speed of any one of the word lines is detected to be greater than the reference value, the bonding defect detector 1260 can determine the corresponding word line bonding as an open defect. Or, if the precharge speed of any one of the word lines is detected to be less than the reference value, the bonding defect detector 1260 can determine the corresponding word line bonding as a resistive defect. In addition, if the development speed of any one of the word lines is detected to be lower than the reference value, the bonding defect detector 1260 can determine the corresponding word line bonding as a short defect.

As described above, the non-volatile memory device 1200 includes the bonding defect detector 1260. The bonding defect detector 1260 can detect a word line loading characteristic according to the magnitude of the bonding resistance during a defect test of the non-volatile memory device 1200. By the detection function of the word line loading characteristic described above, the non-volatile memory device 1200 can detect all of an open defect, a resistive defect, and a short defect of word line bonding 400.

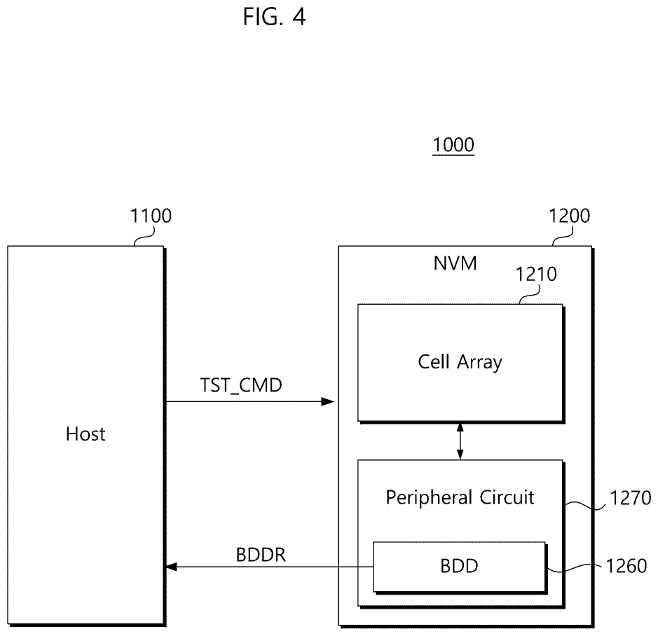

FIG. 4 is a block diagram showing a memory system according to an embodiment. Referring to FIG. 4, the memory system 1000 may include a host 1100 and at least one non-volatile memory device 1200. Here, the host 1100 may be a memory controller, and the memory system 1000 may be a data storage medium such as a memory card, a USB memory, an SSD, etc. Or, the host 1100 may be a test device, and the non-volatile memory device 1200 may be a device under test DUT in which the presence of a bonding defect is detected. Hereinafter, the host 1100 will be considered as a test device for detecting the bonding defect.

The host 1100 may transmit a test command TST_CMD or a request to the non-volatile memory device 1200 to detect a bonding defect. In response to the test command TST_CMD, the non-volatile memory device 1200 will provide a bonding defect detection result BDDR. Then, the host 1100 will designate the DUT as a good product if it is normal, and will perform an analysis according to the type of bonding defect for the DUT with a bonding defect.

The non-volatile memory device 1200 may include a cell array 1210 and a peripheral circuit 1270. The peripheral circuit 1270 may include a bonding defect detector 1260. As described above, the bonding defect detector 1260 may detect the word line loading characteristic according to the magnitude of the bonding resistance for each word line during a defect test of the non-volatile memory device 1200. By the detection function of the word line loading characteristic described above, the non-volatile memory device 1200 can detect all of the open defect, resistive defect, and short defect of word line bonding. The bonding defect detector 1260 can provide a detected bonding defect detection result BDDR to the host 1100.

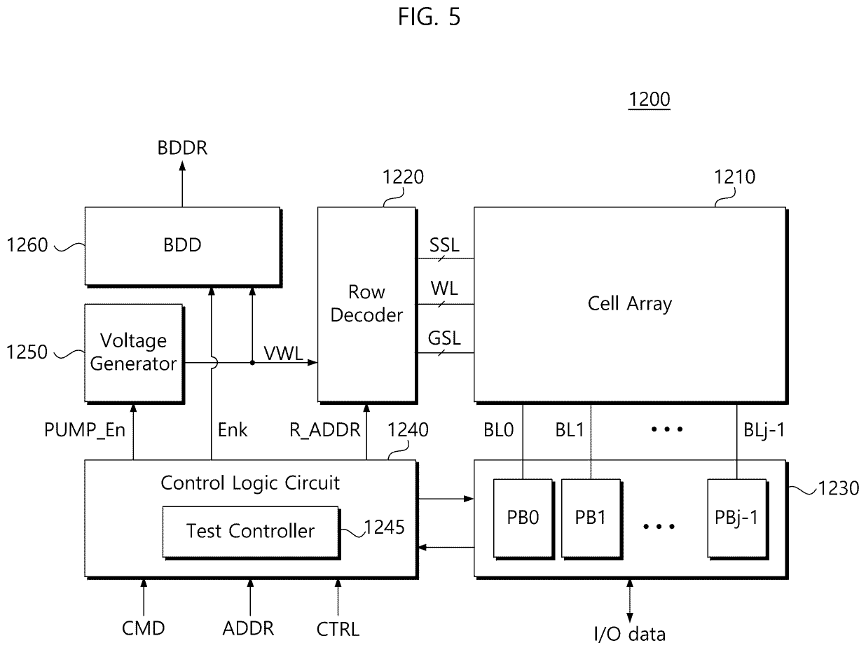

FIG. 5 is a block diagram showing a non-volatile memory device according to an embodiment. Referring to FIG. 5, a non-volatile memory device 1200 may include a cell array 1210, a row decoder 1220, a page buffer circuit 1230, a control logic circuit 1240, a voltage generator 1250, and a bonding defect detector 1260.

The cell array 1210 is connected to the row decoder 1220 through word lines WLs and select lines SSL and GSL. The cell array 1210 is connected to the page buffer circuit 1230 through bit lines BLs. The cell array 1210 may include a plurality of NAND cell strings. The channel of each of the cell strings may be formed in a vertical direction on the substrate. The cell array 1210 will include a plurality of memory cells forming a cell string. The plurality of memory cells can be programmed, erased, and sensed by voltages provided to bit lines BLs or word lines WLs. The program operation can be performed in units of pages, and the erase operation can be performed in units of blocks.

The row decoder 1220 can select any one of the memory blocks of the cell array 1210 in response to a row address R_ADDR. The row decoder 1220 can select any one of the word lines of the selected memory block in response to the row address R_ADDR. The row decoder 1220 transfers a word line voltage VWL corresponding to the operation mode to the word line of the selected memory block. During the program operation, the row decoder 1220 transfers a program voltage and a verification voltage to the selected word line, and a write pass voltage to the unselected word line. During a read operation, the row decoder 1220 transmits a read voltage to a selected word line and a read pass voltage to a non-selected word line. During the test operation, the row decoder 1220 can sequentially select multiple word lines and perform precharge and development of the word line voltage VWL.

The page buffer circuit 1230 operates as a write driver or a sense amplifier. During a program operation, the page buffer circuit 1230 transmits a bit line voltage corresponding to data to be programmed to the bit lines BLs of the cell array 1210. During a data read operation or a verification read operation, the page buffer circuit 1230 detects data stored in the selected memory cell through the bit lines BLs.

The control logic circuit 1240 controls the page buffer circuit 1230, the row decoder 1220, and the voltage generator 1250 in response to a command CMD transmitted from the outside. The control logic circuit 1240 can control the voltage generator 1250, the page buffer circuit 1230, and the row decoder 1220 to perform program, read, and erase operations on the selected memory cell according to the command CMD. The control logic circuit 1240 can transmit a row address R_ADDR to the row decoder 1220 and provide a pumping enable signal PUMP_En to the voltage generator 1250.

In particular, the control logic circuit 1240 can include a test controller 1245. The test controller 1245 generates enable signals (Enk, k=1, 2, 3) that activate the bonding defect detector 1260 in response to a test command TST_CMD from the host 1100. The test controller 1245 transmits the word line voltage VWL output from the voltage generator 1250 to the selected word line by sequentially activating or deactivating the enable signals Enk. In addition, the test controller 1245 can control the precharge and development process for the selected word line to support the detection operation of the bonding defect detector 1260. The operation of the test controller 1245 will be described in more detail through the waveform diagram described below.

The voltage generator 1250 generates various types of word line voltages VWL to be supplied to each word line according to the control logic circuit 1240 and voltages to be supplied to the bulk (e.g., well region) where the memory cells are formed. The word line voltage VWL to be supplied to each word line include a program voltage Vpgm, a write pass voltage Vpass, a read voltage Vrd, and a read pass voltage Vread. In the test mode for identifying a defect in word line bonding, the voltage generator 1250 generates a word line voltage VWL for precharging the selected word line.

The bonding defect detector 1260 precharges the selected word line in response to enable signals Enk from the test controller 1245. The bonding defect detector 1260 can identify an open defect or a resistive defect in the word line bonding WLB by detecting a precharge speed or a rising slope of the precharge voltage of the selected word line. In addition, the bonding defect detector 1260 detects a development characteristic of the precharged word line in response to enable signals Enk from the test controller 1245. Based on the detected development characteristic, the bonding defect detector 1260 can identify whether the corresponding word line bonding WLB has a short defect. The bonding defect detector 1260 can provide the presence or absence of a defect in the detected word line bonding WLB and the type of defect as a bonding defect detection result BDDR. The bonding defect detection result BDDR will be provided to the host 1100 that requested the test of the non-volatile memory device 1200.

As described above, the non-volatile memory device 1200 can identify the presence or absence of a defect in the word line bonding WLB and the type of defect through the bonding defect detector 1260. In particular, the bonding defect detector 1260 can detect all open defect, resistive defect, and short defects through one word line precharge operation. The bonding defect detector 1260 can provide the bonding defect detection result BDDR generated as a detection result to the host 1100.

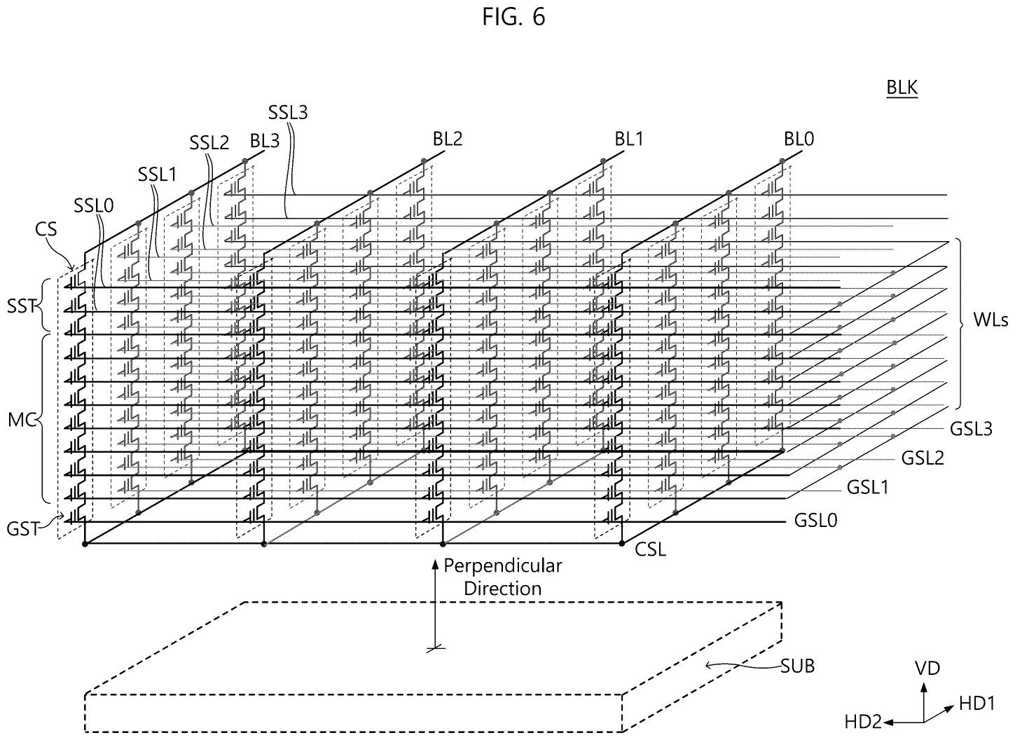

FIG. 6 is a circuit diagram showing a structure of a memory block constituting the cell array of FIG. 5 according to an embodiment. Referring to FIG. 6, cell strings CS are formed between bit lines BL0, BL1, BL2 and BL3 and a common source line CSL to configure a memory block BLK.

A plurality of cell strings are formed between the bit line BL0 and the common source line CSL. The string selection transistors SST of the cell strings CS are connected to the corresponding bit lines BL. The ground selection transistors GST of the cell strings CS are connected to the common source line CSL. Memory cells MCs are provided between the string selection transistors SST and the ground selection transistors GST of the cell strings CS.

Each of the cell strings CS includes the ground selection transistor GST. The ground selection transistors included in the cell strings CS can be controlled by the ground select line GSL. Or, the cell strings corresponding to each row may be controlled by different ground selection lines.

In the above, the circuit structure of the memory cells included in one memory block BLK has been briefly described. However, the circuit structure of the illustrated memory block is a simplified structure for convenience of explanation, and the actual memory block is not limited to the illustrated example. That is, it will be well understood that one physical block may include more semiconductor layers, bit lines BLs, and string selection lines SSLs.

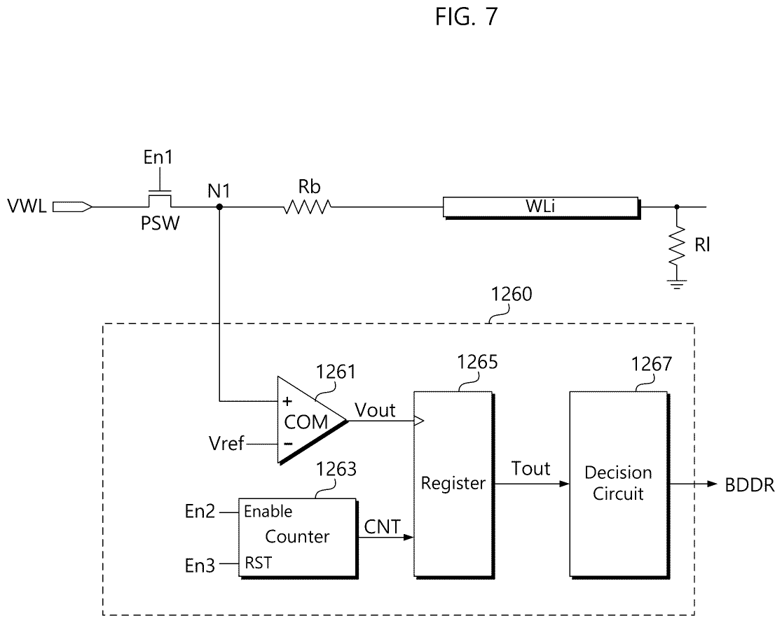

FIG. 7 is a block diagram showing a configuration of the bonding defect detector of FIG. 5 according to an embodiment. Referring to FIG. 7, the bonding defect detector 1260 can detect a precharge or development characteristic of a word line (WLi, ‘i’ is a natural number) to which a word line voltage VWL is provided.

When the bonding defect test starts, the test controller (1245, see FIG. 5) will activate the first enable signal En1 and the second enable signal En2 to a high level. The power switch PSW is turned on according to the activation of the first enable signal En1. Then, the word line voltage VWL supplied from the voltage generator 1250 is transmitted to the first node N1 and to the word line WLi via the bonding resistance Rb. That is, the precharge of the word line WLi occurs by the first enable signal En1. The precharge speed of the word line WLi is affected by the word line loading resistance R1. However, the size of the word line loading resistance R1 is considered to be constant. Therefore, the precharge speed of the word line WLi can be determined according to the bonding resistance Rb corresponding to the characteristic of the word line bonding WLB.

The bonding defect detector 1260 can detect the precharge speed or development characteristic of the word line WLi that varies according to the magnitude of the bonding resistance Rb. For this purpose, the bonding defect detector 1260 can include a comparator 1261, a counter 1263, a register 1265, and a decision circuit 1267.

The comparator 1261 compares the level of the word line voltage VWL transmitted to the first node N1 with the reference voltage Vref. The comparator 1261 transitions the comparison result Vout to a high level at the moment when the word line voltage VWL becomes higher than the reference voltage Vref. The comparator 1261 can transition the comparison result Vout to a low level at the moment when the word line voltage VWL becomes lower than the reference voltage Vref.

The counter 1263 starts a counting operation at a preset cycle according to the activation of the second enable signal En2. The counter 1263 outputs the count value CNT to the register 1265. When the third enable signal En3 is activated, the counter 1263 can initialize or reset the count value CNT being counted.

The register 1265 latches the count value CNT output from the counter 1263 according to the comparison result Vout. Then, the register 1265 transfers the latched count value CNT to the decision circuit 1267 as a detection count Tout. In particular, the register 1265 can latch the count value CNT when the comparison result Vout transitions from a low level to a high level in the precharge section of the word line WLi and output the latched count value CNT as the detection count Tout. In addition, the register 1265 latches the count value CNT when the comparison result Vout transitions from a high level to a low level in the development section of the word line WLi. Then, the register 1265 transfers the latched count value CNT to the decision circuit 1267 as a detection count Tout.

The decision circuit 1267 identifies the presence of a bonding defect and the type of the bonding defect based on the detection count Tout. That is, the decision circuit 1267 can determine the type of the bonding defect based on the detection count Tout that occurs in the precharge section of the word line WLi. If the detection count Tout is smaller than the first reference value Tref1, the decision circuit 1267 can determine that the precharge speed of the word line WLi is higher than the reference speed. That is, if the detection count Tout is smaller than the first reference value Tref1, the decision circuit 1267 can determine that there is an open defect. On the other hand, if the detection count Tout is larger than the second reference value (Tref2>Tref1), the decision circuit 1267 can determine that the precharge speed of the word line WLi is lower than the reference speed. That is, if the detection count Tout is greater than the second reference value Tref2, the decision circuit 1267 can determine that there is a resistive defect. If the detection count Tout corresponds between the first reference value Tref1 and the second reference value Tref2, the decision circuit 1267 can determine that there is no bonding defect.

The decision circuit 1267 can determine the type of bonding defect based on the detection count Tout that occurs in the development section of the word line WLi. The decision circuit 1267 can provide the determined type of bonding defect as a bonding defect detection result BDDR. If the detection count Tout is less than the third reference value Tref3, the decision circuit 1267 can determine that the discharge speed of the word line WLi is higher than the reference. That is, if the detection count Tout is less than the third reference value Tref3, the decision circuit 1267 can determine that the bonding defect is a short defect. On the other hand, if the detection count Tout is greater than the third reference value Tref3 or does not occur, the decision circuit 1267 can determine that the precharge speed of the word line WLi is lower than the reference. That is, if the detection count Tout is greater than the third reference value Tref3 or does not occur, the decision circuit 1267 can determine that there is no short defect.

As described above, the bonding defect detector 1260 can output the presence of a bonding defect or the type of the bonding defect as a bonding defect detection result BDDR value according to the precharge or development characteristics of the detected word line WLi.

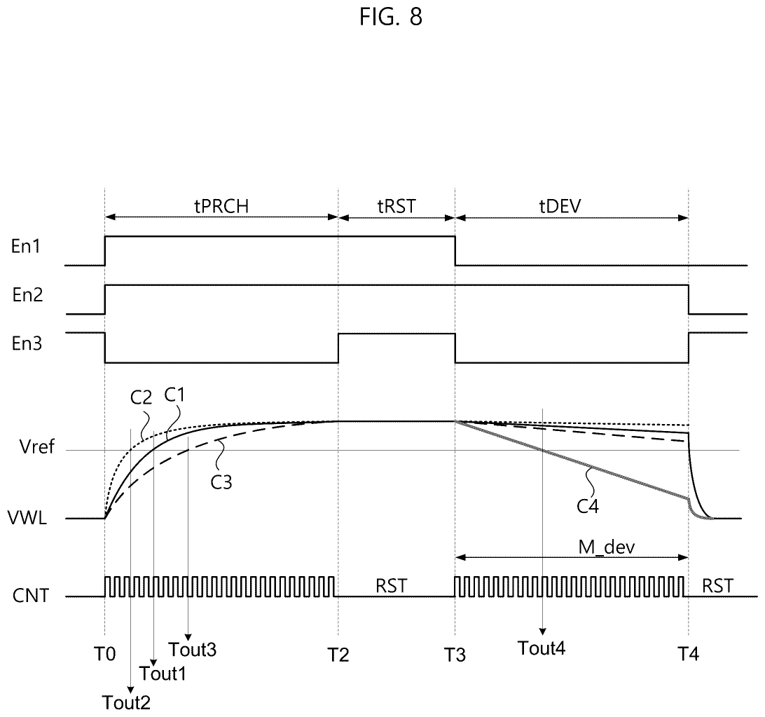

FIG. 8 is a waveform diagram showing a bonding defect test operation performed in the bonding defect detector of FIG. 7. Referring to FIG. 8, the bonding defect detector 1260 can sense the precharge speed and the development speed of the word line WLi being precharged in response to the enable signals En1, En2 and En3 to identify the type of bonding defect.

At time T0, the bonding defect test starts. The test controller (1245, see FIG. 5) will activate the first enable signal En1 and the second enable signal En2 to a high level, and deactivate the third enable signal En3. The power switch PSW is turned on according to the activation of the first enable signal En1, and the word line voltage VWL is transmitted to the first node N1. The word line voltage VWL transmitted to the first node N1 precharges the word line WLi via the bonding resistance Rb. The count operation of the counter (1263, see FIG. 7) is activated according to the activation of the second enable signal En2. That is, the counter 1263 can sequentially count-up or count-down the count value CNT.

The waveform of the word line voltage VWL precharged to the word line WLi is illustrated as three curves according to the bonding resistance Rb. First, the first curve C1 shows the change in the word line voltage VWL when the magnitude of the bonding resistance Rb is an appropriate size, i.e., a normal value. The second curve C2 shows the change in the word line voltage VWL when the magnitude of the bonding resistance Rb is small and the time constant is relatively small. That is, the second curve C2 shows a relatively fast increase rate of the word line voltage VWL. The third curve C3 shows a change in the word line voltage VWL when the bonding resistance Rb is large and the time constant is increased compared to the normal case. That is, the third curve C3 shows a relatively slow increase rate of the word line voltage VWL.

First, when the test operation is performed when the bonding resistance Rb is normal, the change in the word line voltage VWL is shown as the first curve C1. Therefore, the first detection count Tout1 at the point where the word line voltage VWL becomes higher than the reference voltage Vref is latched by the register 1265. The first detection count Tout1 will be identified as being within the normal range by the decision circuit 1267. Therefore, the decision circuit 1267 will output the bonding defect detection result BDDR as normal.

If the test operation is performed when the magnitude of the bonding resistance Rb is smaller than the normal value, the change in the word line voltage VWL appears as the second curve C2. Therefore, the second detection count Tout2 at the point in time when the word line voltage VWL becomes higher than the reference voltage Vref is latched by the register 1265. The second detection count Tout2 will be identified as an open defect by the decision circuit 1267. Therefore, the decision circuit 1267 will output the bonding defect detection result BDDR as an open defect.

If the test operation is performed when the magnitude of the bonding resistance Rb is larger than the normal value, the change in the word line voltage VWL appears as the third curve C3. Therefore, the third detection count Tout3 at the point in time when the word line voltage VWL becomes higher than the reference voltage Vref is latched by the register 1265. The third detection count Tout3 will be identified as a resistive defect by the decision circuit 1267. Therefore, the decision circuit 1267 will output the bonding defect detection result BDDR as a resistive defect.

The precharge period tPRCH of the word line WLi ends at the point in time T2, and at the same time, the reset period tRST starts. The reset in the reset period tRST indicates the reset of the counter 1263. That is, the precharged word line voltage VWL in the reset period tRST is maintained, and only the counter 1263 is initialized. To this end, during the reset period tRST, the test controller 1245 will maintain the first enable signal En1 and the second enable signal En2 at high level, and output the third enable signal En3 at high level. In response to the transition of the third enable signal En3 to high level, the counter 1263 initializes the count value CNT.

From time T3, the development period tDEV begins. The test controller 1245 transitions the first enable signal En1 to a low level to turn off the power switch PSW. Then, the supply of the word line voltage VWL to the word line WLi is stopped, and the development of the precharged word line WLi occurs. At the same time, the counting operation of the initialized counter 1263 starts according to the activation of the second enable signal En2.

In the development period tDEV, a short defect of the word line bonding is detected. If the charge charged in the word line WLi is discharged excessively at a high speed, it can be identified as the short defect of the word line bonding. The development characteristic of the word line WLi in the case of the short defect is illustrated by the fourth curve C4. The fourth detection count Tout4 at the point in time when the level of the word line voltage VWL becomes lower than the reference voltage Vref is latched by the register 1265. The fourth detection count Tout4 will be identified as the short defect by the decision circuit 1267. Then, the decision circuit 1267 will output the bonding defect detection result BDDR as the short defect. At the time point T4 when the development period tDEV ends, the test controller 1245 deactivates the first enable signal En1 and the second enable signal En2 to a low level, and activates the third enable signal En3 to a high level. Then, the counter 1263 can be initialized again.

The open defect, resistive defect, and short defect detection operations of the bonding defect detector 1260 have been described above. The bonding defect detector 1260 can easily identify the type of bonding defect by sensing the precharge speed and development characteristics of the word line WLi that is precharged in response to the enable signals En1, En2 and En3 using the counter 1263.

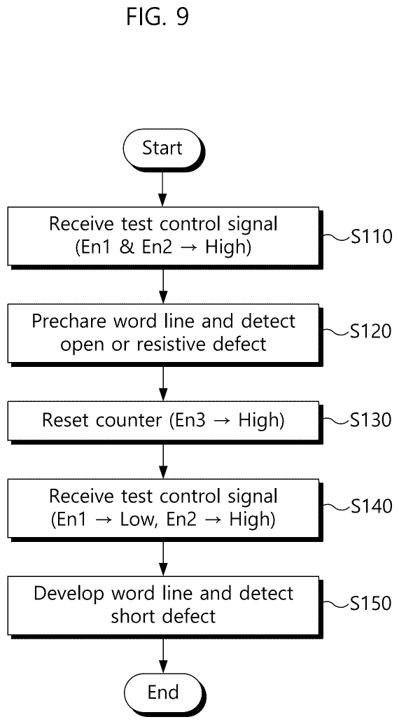

FIG. 9 is a flowchart showing a test operation for defect detection performed in a bonding defect detector according to an embodiment. Referring to FIG. 9, the bonding defect detector 1260 can detect all of open defect, resistive defect, and short defect through one precharge for a selected word line.

In step S110, the bonding defect detector 1260 receives test control signals or enable signals provided from the test controller 1245. The test controller 1245 activates the first and second enable signals En1 and En2 to a high level and deactivates the third enable signal En3 to a low level. Then, the power switch PSW is turned on, and the count operation of the counter (1263, see FIG. 7) is activated.

In step S120, the word line voltage VWL is transmitted to the word line WLi according to the turn-on of the power switch PSW. Then, detection of an open defect or a resistive defect is performed in the precharge period of the word line WLi. For example, a point in time when the word line voltage VWL becomes higher than the reference voltage Vref is detected by a comparator (1261, see FIG. 7). Then, a count value CNT at the point in time when the word line voltage VWL becomes higher than the reference voltage Vref is latched as a detection count Tout in a register (1265, see FIG. 7). A decision circuit (1267, see FIG. 7) determines whether the bonding defect corresponds to an open defect, normal, or resistive defect according to the size of the detection count Tout. And the decision circuit 1267 will output the bonding defect detection result BDDR according to the decision result.

In step S130, the counter 1263 is reset. To reset the counter 1263, the test controller 1245 maintains the first enable signal En1 and the second enable signal En2 at a high level, and transitions the third enable signal En3 to a high level. In response to the transition of the third enable signal En3 to a high level, the counter 1263 initializes the count value CNT.

In step S140, the bonding defect detector 1260 receives a test control signal provided from the test controller 1245. The test controller 1245 transitions the first enable signal En1 to a low level to turn off the power switch PSW. Then, the supply of the word line voltage VWL to the word line WLi is stopped, and the development of the precharged word line WLi starts. At the same time, the second enable signal En2 is maintained at a high level, and the third enable signal En3 is deactivated to a low level. Then, the count operation of the initialized counter 1263 starts.

In step S150, the presence of a short defect in the word line bonding is detected through detection of the development characteristic of the voltage charged in the word line WLi. If the charge charged in the word line WLi is discharged excessively at a high speed, it can be identified as a short defect in the word line bonding. The count value CNT at the point in time when the level of the word line voltage VWL becomes lower than the reference voltage Vref is latched as a detection count Tout in the register 1265. And based on the detection count Tout, the presence or absence of a short defect will be identified.

In the above, the method of detecting the open defect, the resistive defect, and the short defect of the bonding defect detector 1260 has been described. The bonding defect detector 1260 can easily identify the type of bonding defect by sensing the precharge and development characteristics of the word line WLi.

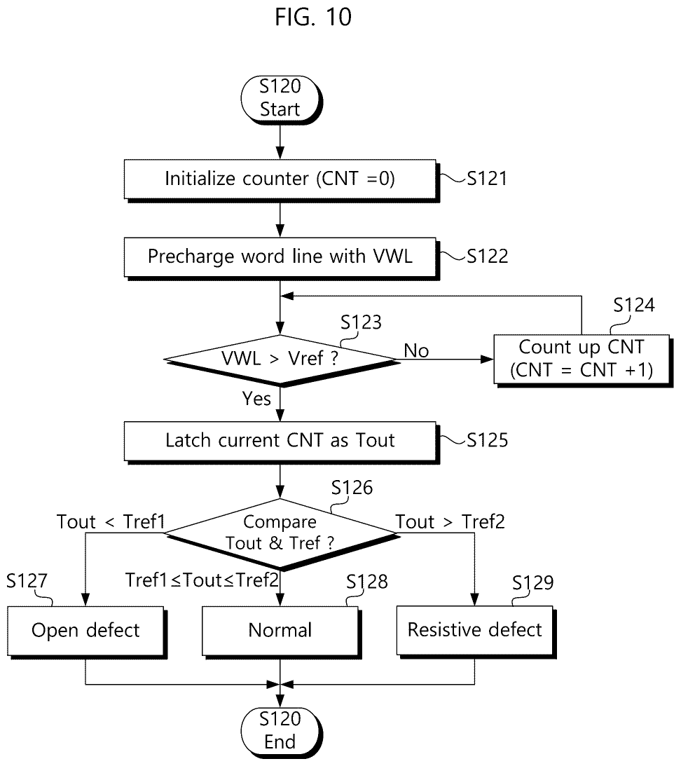

FIG. 10 is a flowchart showing step S120 of FIG. 9 in more detail. Referring to FIG. 10, the bonding defect detector 1260 can identify the type of bonding defect by detecting the precharge speed of the word line WLi. That is, the bonding defect detector 1260 can determine whether the bonding defect corresponds to an open defect, normal, or resistive defect in the precharge section of the word line WLi.

In step S121, the counter 1263 is initialized. The count value CNT can be initialized to ‘0’ by the activation of the third enable signal En3 from the test controller 1245. Following the initialization, the count operation of the counter 1263 starts.

In step S122, the power switch PSW is turned on according to the activation of the first enable signal En1. Then, the word line WLi is precharged by the word line voltage VWL provided from the voltage generator 1250.

In step S123, the point in time when the word line voltage VWL being precharged becomes higher than the reference voltage Vref is detected by the comparator (1261, see FIG. 7). If the word line voltage VWL is determined to be higher than the reference voltage Vref (‘Yes’ direction), the procedure moves to step S125. On the other hand, if the word line voltage VWL is determined to be not higher than the reference voltage Vref (‘No’ direction), the procedure moves to step S124.

In step S124, the count value CNT of the counter 1263 is increased. After that, the procedure returns to step S123 to perform a comparison between the word line voltage VWL being precharged and the reference voltage Vref under the condition of the increased count value (CNT+1).

In step S125, the count value CNT at the point where the word line voltage VWL is higher than the reference voltage Vref is latched by the register (1265, see FIG. 7). The register 1265 outputs the latched count value CNT as a detection count Tout. The detection count Tout is provided to the decision circuit 1267.

In step S126, the decision circuit 1267 compares the detection count Tout with reference values. That is, the decision circuit 1267 determines the type or existence of the bonding defect according to the size of the detection count Tout. If the detection count Tout is less than the first reference value Tref1, the procedure moves to step S127. On the other hand, if the detection count Tout is greater than or equal to the first reference value Tref1 and less than or equal to the second reference value (Tref2>Tref1), the procedure moves to step S128. And if the detection count Tout is greater than the second reference value Tref2, the procedure moves to step S129.

In step S127, the decision circuit 1267 determines that the precharge speed of the word line WLi corresponds to the open defect. And the decision circuit 1267 will output the determination result as a bonding defect detection result BDDR.

In step S128, the decision circuit 1267 determines that there is no bonding defect. That is, the decision circuit 1267 determines that the magnitude of the bonding resistance Rb is within a normal range. And the decision circuit 1267 will output the determination result corresponding to normal as the bonding defect detection result BDDR.

In step S129, the decision circuit 1267 determines that the precharge speed of the word line corresponds to the resistive defect. And the decision circuit 1267 will output the decision result corresponding to the resistive defect as the bonding defect detection result BDDR.

In the above, the bonding defect detection method of detecting the precharge speed of the word line WLi has been described. In the precharge section of the word line WLi, the bonding defect detector 1260 can identify open defect and resistive defect, respectively.

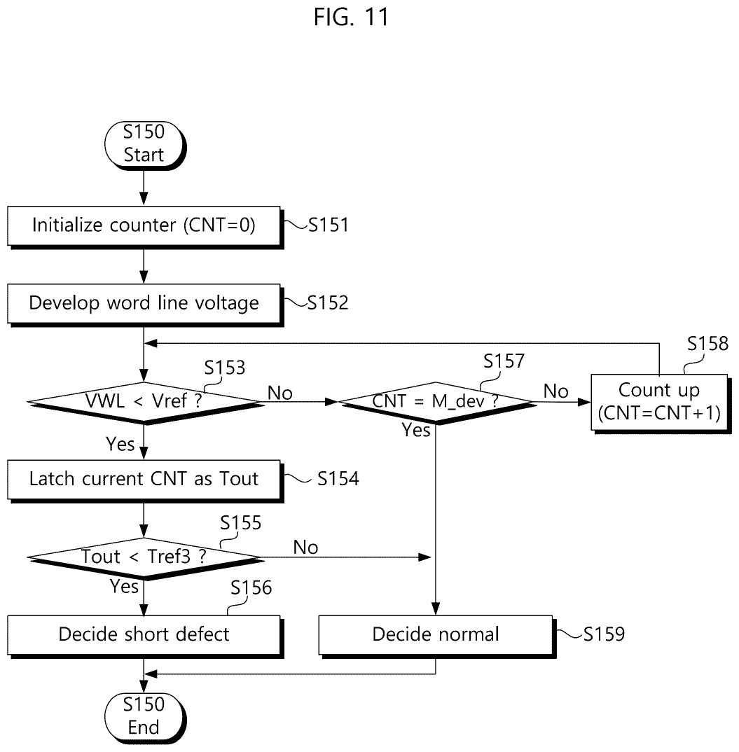

FIG. 11 is a flowchart showing step S150 of FIG. 9 in more detail. Referring to FIG. 11, the bonding defect detector 1260 can identify a short defect of bonding by detecting the development characteristic of the word line WLi. That is, the bonding defect detector 1260 can determine whether the short defect exists by detecting whether a leakage current exists in the development section of the precharged word line WLi.

In step S151, the counter 1263 is initialized. The counter 1263 is reset according to the activation of the third enable signal En3 from the test controller 1245. Then, the count value CNT is initialized to ‘0’. After the initialization, the count operation of the counter 1263 starts.

In step S152, the power switch PSW is turned off as the first enable signal En1 transitions to a low level. Then, the development of the word line WLi precharged to the word line voltage VWL level begins. The development speed or discharge speed of the word line WLi will be faster if there is a leakage current between word line bonds.

In step S153, the point in time when the word line voltage VWL being developed becomes lower than the reference voltage Vref is detected by the comparator (1261, see FIG. 7). If the word line voltage VWL is determined to be lower than the reference voltage Vref (‘Yes’ direction), the procedure moves to step S154. On the other hand, if it is determined that the word line voltage VWL is not lower than the reference voltage Vref (‘No’ direction), the procedure moves to step S157.

In step S154, the count value CNT at the point in time when the word line voltage VWL becomes lower than the reference voltage Vref is latched by the register (1265, see FIG. 7). The register 1265 outputs the latched count value CNT as a detection count Tout. The detection count Tout is provided to the decision circuit 1267.

In step S155, the decision circuit 1267 compares the detection count Tout with the third reference count Tref3. If the detection count Tout is lower than the third reference count Tref3, the procedure moves to step S156. On the other hand, if the detection count Tout is not smaller than the third reference count Tref3, the procedure moves to step S159.

In step S156, the decision circuit 1267 determines the bonding defect as a short defect. Then, the decision circuit 1267 will output the determination result as a bonding defect detection result BDDR.

In step S157, it is determined whether the current count value CNT has reached the development maximum count M_dev. If it is determined that the current count value CNT has reached the development maximum count M_dev (‘Yes’ direction), the procedure moves to step S159. On the other hand, if it is determined that the current count value CNT has not reached the development maximum count M_dev (‘No’ direction), the procedure moves to step S158.

In step S158, the counter 1263 increases the count value CNT. After that, the procedure returns to step S153 to perform a comparison of the word line voltage VWL and the reference voltage Vref under the condition of the increased count value (CNT+1).

In step S159, the decision circuit 1267 determines that there is no bonding defect. That is, the decision circuit 1267 determines that there is no leakage in the word line bonding and that it is normal. Then, the decision circuit 1267 will output the judgment result corresponding to normal as the bonding defect detection result BDDR.

In the above, the short defect detection method of the word line bonding has been described by detecting the development characteristic of the word line WLi. By the above-described procedures, the bonding defect detector 1260 can identify whether there is a short defect in the development section of the word line WLi.

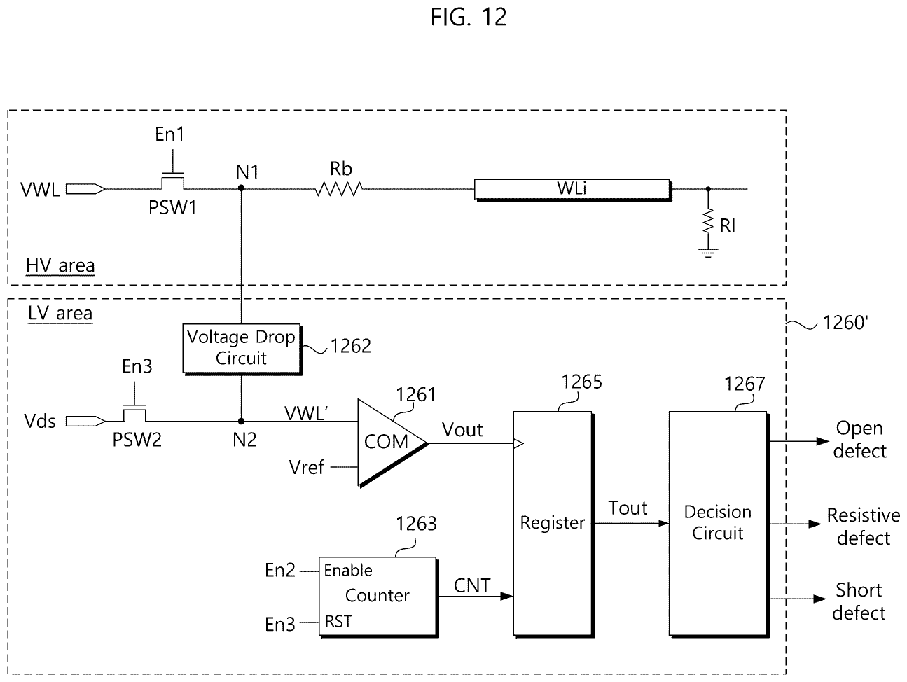

FIG. 12 is a block diagram showing the bonding defect detector of FIG. 5 according to an embodiment. Referring to FIG. 12, the bonding defect detector 1260′ of another embodiment may include a voltage drop circuit 1262 that level-shifts the precharged and developed word line voltage VWL to a low voltage.

The word line voltage VWL generated by the voltage generator 1250 is provided as a high voltage for a program or read operation. On the other hand, the peripheral circuit (1270, see FIG. 4) in which the page buffer circuit (1230, see FIG. 5) or the control logic circuit (1240, see FIG. 5) is formed may be driven under a low voltage condition. Furthermore, the driving voltage provided to the peripheral circuit 1270 is gradually decreasing in accordance with the low-power trend of the non-volatile memory device 1200 or the mobile device. Finally, in order to detect the precharge and development characteristics of the word line voltage VWL provided in the high voltage area (HV area) in the low voltage area (LV area), a configuration for voltage drop is required. Therefore, the bonding defect detector 1260′ may include the voltage drop circuit 1262 for shifting the level of the word line voltage VWL to low voltage.

When the test starts, the test controller (1245, see FIG. 5) will activate the first enable signal En1 and the second enable signal En2 to a high level, and deactivate the third enable signal En3 to a low level. The first power switch PSW1 is turned on according to the activation of the first enable signal En1. Then, the word line voltage VWL supplied from the voltage generator 1250 is transmitted to the first node N1 and transmitted to the word line WLi via the bonding resistance Rb. According to the activation of the first enable signal En1, the word line WLi is precharged to the high-voltage word line voltage VWL.

The bonding defect detector 1260′ can detect the precharge speed or development characteristics of the word line WLi by lowering the word line voltage VWL transmitted to the first node N1 to a low-voltage level. To this end, the bonding defect detector 1260′ may include a comparator 1261, a voltage drop circuit 1262, a counter 1263, a register 1265, and a decision circuit 1267. In addition, a second power switch PSW2 is further included to set the development start voltage Vds of the second node N2 during the development section of the word line voltage VWL. The second power switch PSW2 is controlled by the third enable signal En3 provided to the counter 1263.

The comparator 1261 compares the lowered word line voltage VWL′ of the second node N2 whose word line voltage VWL is level-converted with the reference voltage Vref. The comparator 1261 transitions the comparison result Vout to a high level at the moment when the word line voltage VWL′ that has been lowered than the reference voltage Vref becomes higher. The comparator 1261 can transition the comparison result Vout to a low level at the moment when the lowered word line voltage VWL′ that has been lowered than the reference voltage Vref becomes lower. In particular, in the reset section of the counter 1263 in which the third enable signal En3 is activated, the second node N2 can be reset to the development start voltage Vds. That is, when the second power switch PSW2 is turned on by the third enable signal En3, the lowered word line voltage VWL′ transmitted to the second node N2 is set to the development start voltage Vds.

The counter 1263 starts a count operation at a preset cycle according to the activation of the second enable signal En2. The counter 1263 outputs the count value CNT to the register 1265. When the third enable signal En3 is activated, the counter 1263 initializes or resets the count value CNT. At this time, the voltage of the second node N2 constituting the input terminal of the comparator 1261 is also initialized to the development start voltage Vds.

The register 1265 latches the count value CNT output from the counter 1263 according to the comparison result Vout. Then, the register 1265 provides the latched count value CNT as the detection count Tout to the decision circuit 1267. In particular, the register 1265 can generate the detection count Tout when the comparison result Vout transitions from a low level to a high level in the precharge section of the word line WLi. In addition, the register 1265 can generate the detection count Tout in response to the transition of the comparison result Vout from a high level to a low level in the development section of the word line WLi.

The decision circuit 1267 identifies the presence of the bonding defect and the type of the bonding defect based on the detection count Tout. If the detection count Tout is smaller than the first reference value Tref1 in the precharge section of the word line, the decision circuit 1267 can determine that it is an open defect. On the other hand, if the detection count Tout is larger than the second reference value (Tref2>Tref1), the decision circuit 1267 can determine that it is the resistive defect. If the detection count Tout is equal to or greater than the first reference value Tref1 and equal to or less than the second reference value Tref2 in the precharge section of the word line, the decision circuit 1267 can determine that it is normal without the bonding defect.

The decision circuit 1267 can determine the type of bonding defect based on the detection count Tout that occurs in the development section of the word line WLi. If the detection count Tout is smaller than the third reference value Tref3, the decision circuit 1267 can determine that the discharge speed of the word line WLi is higher than the reference value. That is, if the detection count Tout is smaller than the third reference value Tref3, the decision circuit 1267 can determine that the bonding defect is the short defect. On the other hand, if the detection count Tout is larger than the third reference value Tref3 or does not generated, it can be determined that there is no short defect.

As described above, the bonding defect detector 1260′ can identify the presence of a bonding defect and the type of the bonding defect by monitoring the word line voltage VWL′ lowered to a low voltage level.

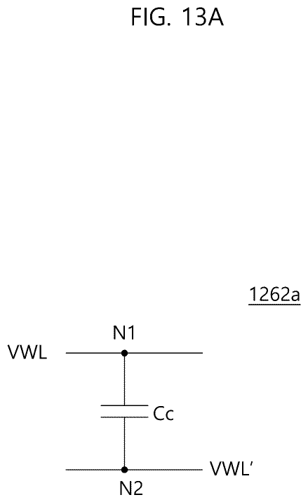

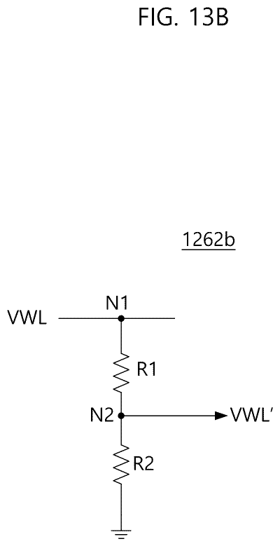

FIGS. 13A and 13B are circuit diagrams of the voltage drop circuit of FIG. 12 according to embodiments. FIG. 13A shows a case where the voltage drop circuit 1262a is configured using a coupling capacitor Cc. FIG. 13B shows a case where the voltage drop circuit 1262b is configured using a voltage dividing circuit.

Referring to FIG. 13A, the voltage drop circuit 1262a according to one embodiment can lower the word line voltage VWL supplied from the voltage generator (1250, see FIG. 5) to the first node N1 using the coupling capacitor Cc. The word line voltage VWL′ lowered by the coupling capacitor Cc can be transmitted to the second node N2 connected to the input terminal of the comparator 1261. The drop ratio of the word line voltage VWL and the lowered word line voltage VWL′ can be controlled by selecting the capacitance of the coupling capacitor Cc.

Referring to FIG. 13B, a voltage drop circuit 1262b according to another embodiment can lower the word line voltage VWL supplied from the voltage generator 1250 to the first node N1 through voltage dividing. The word line voltage VWL supplied to the first node N1 can be distributed using at least two resistors R1 and R2 connected in series. And the voltage divided to the resistor R2 can be used as the lowered word line voltage VWL′ and provided to the input terminal of the comparator 1261. The drop ratio of the word line voltage VWL and the lowered word line voltage VWL′ can be controlled by adjusting the resistance ratio of the resistors R1 and R2.

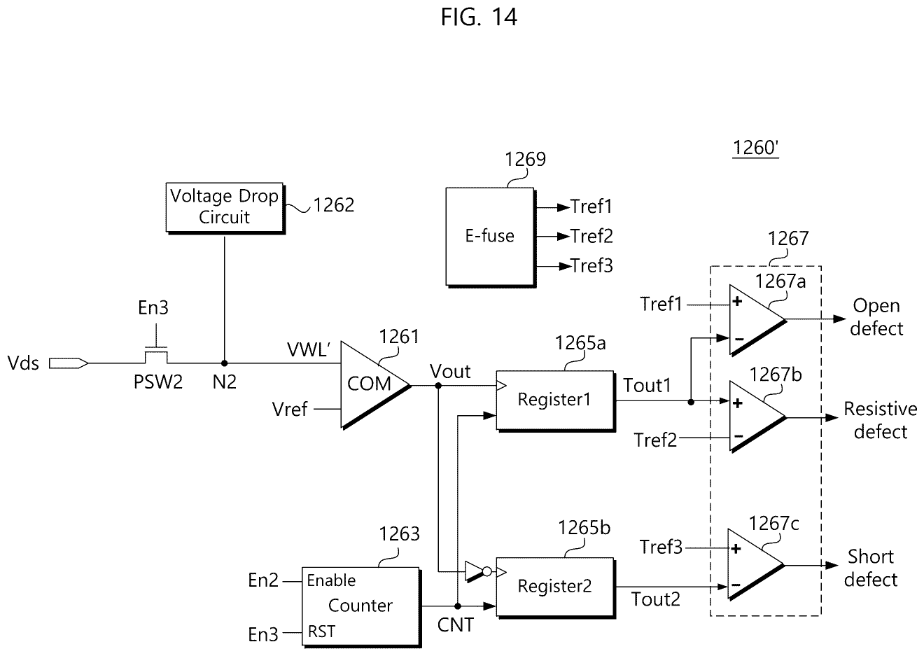

FIG. 14 is a block diagram showing the configuration of the bonding defect detector of FIG. 12 according to an embodiment. Referring to FIG. 14, the bonding defect detector 1260′ detects a change in the level of a lowered word line voltage VWL′ provided by the voltage drop circuit 1262 to identify the type of bonding defect. To this end, the bonding defect detector 1260′ may include a second power switch PSW2, a comparator 1261, a voltage drop circuit 1262, a counter 1263, registers 1265a and 1265b, a decision circuit 1267, and an E-fuse 1269.

When the first enable signal En1 and the second enable signal En2 are activated to a high level, the first power switch (PSW1, see FIG. 12) is turned on. Then, the word line voltage VWL is supplied to the first node N1. The word line voltage VWL supplied to the first node N1 precharges the word line WLi via the bonding resistance Rb. At the same time, the word line voltage VWL′ lowered by the voltage drop circuit 1262 will be provided to the second node N2.

The comparator 1261 compares the lowered word line voltage VWL′ supplied to the second node N2 with the reference voltage Vref. The comparator 1261 transitions the comparison result Vout to a high level at the moment when the lowered word line voltage VWL′ becomes higher than the reference voltage Vref. The comparator 1261 transitions the comparison result Vout to a low level at the moment when the lowered word line voltage VWL′ is lower than the reference voltage Vref.

The second node N2, which is an input terminal of the comparator 1261, is reset to the development start voltage Vds in the reset section of the counter 1263. That is, when the third enable signal En3 is activated in the reset section, the second power switch PSW2 is turned on. Then, the second node N2 precharged with the lowered word line voltage VWL′ can be reset to the development start voltage Vds. The development start voltage Vds must be higher than the reference voltage Vref.

In the development section where the third enable signal En3 is deactivated, the development of the lowered word line voltage VWL′ of the second node N2 starts at the level of the development start voltage Vds. At this time, the comparator 1261 transitions the comparison result Vout to a low level at the moment when the lowered word line voltage VWL′ becomes lower than the reference voltage Vref.

The counter 1263 starts counting at a preset cycle according to the activation of the second enable signal En2. The counter 1263 outputs the count value CNT to the registers 1265a and 1265b. When the third enable signal En3 is activated, the counter 1263 initializes or resets the count value CNT being counted. At this time, the voltage of the second node N2 constituting the input terminal of the comparator 1261 is also reset to the development start voltage Vds.

The registers 1265a and 1265b generate detection counts (Tout1, Tout2) in response to the comparison result Vout in each of the precharge section and the development section for the lowered word line voltage VWL′. The first register 1265a latches the count value CNT output from the counter 1263 at the point in time when the comparison result Vout transitions from a low level to the high level. The first register 1265a outputs the latched count value CNT as the first detection count Tout1. On the other hand, the second register 1265b latches the count value CNT output from the counter 1263 at the point where the comparison result Vout transitions from the high level to the low level. For this purpose, the inverted comparison result Vout may be provided to the second register 1265b. The second register 1265b outputs the latched count value CNT as a second detection count Tout2.

The decision circuit 1267 determines the presence of a bonding defect and the type of the bonding defect based on the detection counts (Tout1, Tout2). The decision circuit 1267 may include, for example, a first comparator 1267a and a second comparator 1267b for identifying the open defect or the resistive defect in a precharge period. And the decision circuit 1267 may include a third comparator 1267c that identifies whether the short defect exists in the development section.

In the precharge section, the first detection count Tout1 provided from the first register 1265a is provided to the first comparator 1267a and the second comparator 1267b. The first comparator 1267a outputs a high level when the first detection count Tout1 is a value smaller than the first reference value Tref1. That is, when the first detection count Tout1 is smaller than the first reference value Tref1, the first comparator 1267a determines that there is the open defect. On the other hand, the first comparator 1267a outputs a low level when the first detection count Tout1 is equal to or greater than the first reference value Tref1. That is, if the first detection count Tout1 is greater than or equal to the first reference value Tref1, the first comparator 1267a determines that there is no open defect.

The second comparator 1267b outputs the high level when the first detection count Tout1 is greater than the second reference value Tref2. That is, if the first detection count Tout1 is greater than the second reference value Tref2, the second comparator 1267b determines that there is the resistive defect. On the other hand, the second comparator 1267b outputs a low level when the first detection count Tout1 is less than or equal to the second reference value Tref2. That is, if the first detection count Tout1 is less than or equal to the second reference value Tref2, the second comparator 1267b determines that there is not the resistive defect. Therefore, if both the first comparator 1267a and the second comparator 1267b output the low level, it can be determined that there is no open defect and no resistive defect.

In the development section, the second detection count Tout2 provided from the second register 1265b is provided to the third comparator 1267c. The third comparator 1267c outputs the high level when the second detection count Tout2 is a value smaller than the third reference value Tref3. That is, if the second detection count Tout2 is smaller than the third reference value Tref3, the third comparator 1267c determines that there is the short defect. On the other hand, the third comparator 1267c outputs the low level when the second detection count Tout2 is equal to or greater than the third reference value Tref3. That is, if the second detection count Tout2 is greater than or equal to the third reference value Tref3, the third comparator 1267c determines that there is no short defect.

The E-fuse 1269 provides the first to third reference values Tref1, Tref2 and Tref3 for identifying the type of bonding defect to the comparators 1267a, 1267b and 1267c of the decision circuit 1267. The first to third reference values Tref1, Tref2 and Tref3 provided by the E-fuse 1269 can be programmed by an external device of the non-volatile memory device 1200.

As described above, the bonding defect detector 1260′ can easily identify the presence or absence of a bonding defect and the type of the bonding defect by monitoring the lowered word line voltage VWL′.

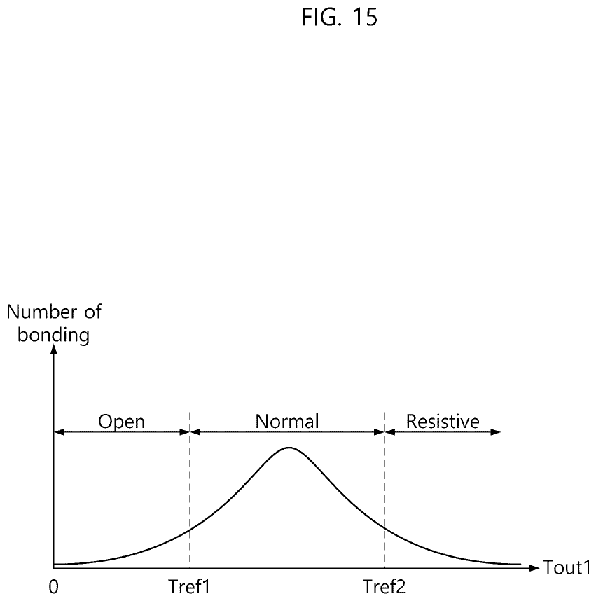

FIG. 15 is a graph showing the first and second reference values provided to the comparators of FIG. 14. Referring to FIG. 15, the distribution of word line bonding according to the detection count Tout follows a normal distribution. Therefore, the decision circuit 1267 can identify whether there is an open defect, normal, or a resistive defect by comparing the first detection count Tout1 and the first reference value Tref1 and the second reference value Tref2 according to the range included therein.

In the precharge section, the first comparator 1267a compares the first detection count Tout1 with the first reference value Tref1. If the first detection count Tout1 is a value smaller than the first reference value Tref1, it can be identified as the open defect. In the precharge section, the second comparator 1267b compares the first detection count Tout1 with the second reference value Tref2. If the first detection count Tout1 is a value greater than the second reference value Tref2, it can be identified as the resistive defect. On the other hand, if the first detection count Tout1 is a value between the first reference value Tref1 and the second reference value Tref2 in the precharge section, the decision circuit 1267 can determine that there is no open defect or resistive defect.

The first reference value Tref1 and the second reference value Tref2 can be programmed into the E-fuse 1269 based on values obtained through various tests or experiments.

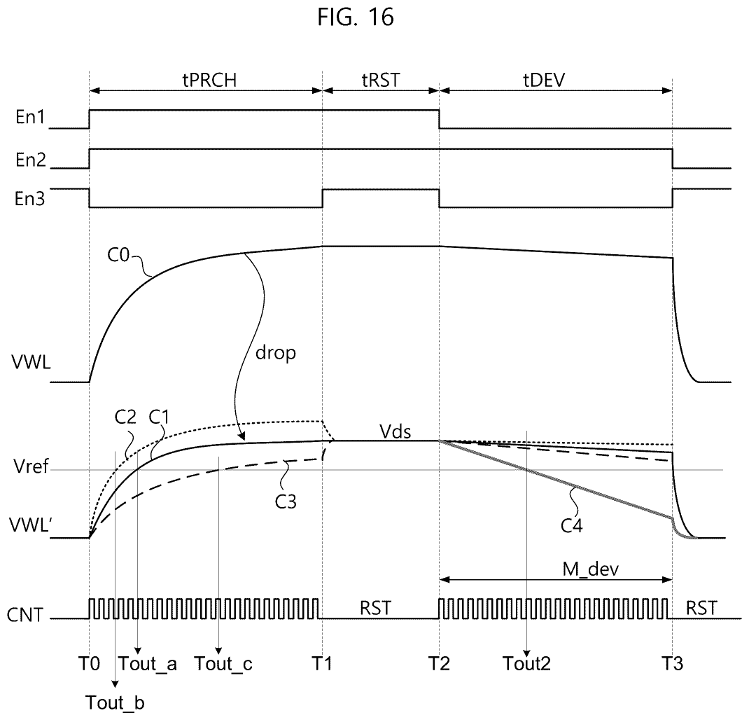

FIG. 16 is a waveform diagram showing the bonding defect test operation of the bonding defect detector of FIG. 14. Referring to FIG. 16, in response to the first enable signal En1, the word line WLi is precharged to word line voltage VWL. At the same time, the lowered word line voltage VWL′ dropped by the voltage drop circuit 1262 will be compared with the reference voltage Vref by the comparator 1261. The bonding defect detector 1260′ can sense the precharge and development characteristics of the lowered word line voltage VWL′ to identify the type of bonding defect.

At time T0, a bonding defect test using the lowered word line voltage VWL′ begins. The test controller (1245, see FIG. 5) will activate the first enable signal En1 and the second enable signal En2 to a high level, and deactivate the third enable signal En3. Upon activation of the first enable signal En1, the first power switch PSW1 is turned on, and the word line voltage VWL is transmitted to the first node N1. The word line voltage VWL transmitted to the first node N1 precharges the word line WLi via the bonding resistance Rb. At the same time, the lowered word line voltage VWL′ dropped by the voltage drop circuit 1262 is transmitted to the comparator 1261. Upon activation of the second enable signal En2, the count operation of the counter (1263, see FIG. 14) is activated. That is, the counter 1263 can sequentially count-up or count-down the count value CNT.

The word line voltage VWL precharged to the word line WLi is illustrated by the curve C0. The word line voltage VWL is provided as a high voltage level. On the other hand, the waveform of the lowered word line voltage VWL′ is exemplarily illustrated as three curves according to the bonding resistance Rb. First, the first curve C1 shows the change in the lowered word line voltage VWL′ when the magnitude of the bonding resistance Rb is normal. The second curve C2 shows the change in the lowered word line voltage VWL′ when the magnitude of the bonding resistance Rb is small. That is, the rising speed of the lowered word line voltage VWL′ shown in the second curve C2 is relatively fast. The third curve C3 shows the change in the lowered word line voltage VWL′ when the magnitude of the bonding resistance Rb is relatively large. That is, the third curve C3 can determine the precharge speed of the lowered word line voltage VWL′ according to the bonding resistance Rb corresponding to the characteristics of the word line bonding WLB.

First, when the magnitude of the bonding resistance Rb is normal, if the test operation is performed, the change in the lowered word line voltage VWL′ appears as the first curve C1. Therefore, the detection count Tout_a at the point in time when the lowered word line voltage VWL′ becomes higher than the reference voltage Vref is latched by the first register 1265a. The detection count Tout_a will be identified as belonging to the normal range by the decision circuit 1267. Therefore, the decision circuit 1267 will output the bonding defect detection result BDDR as normal.

When the test operation is performed when the magnitude of the bonding resistance Rb is a certain amount smaller than the normal value, the change in the lowered word line voltage VWL′ appears as the second curve C2. Therefore, the detection count Tout_b at the point in time when the lowered word line voltage VWL′ becomes higher than the reference voltage Vref is latched by the first register 1265a. The detection count Tout_b will be identified as the open defect by the decision circuit 1267. Therefore, the decision circuit 1267 will output the bonding defect detection result BDDR as the open defect.

When the test operation is performed when the magnitude of the bonding resistance Rb is a certain amount larger than the normal value, the change in the lowered word line voltage VWL′ appears as the third curve C3. Therefore, the detection count Tout_c at the point in time when the lowered word line voltage VWL′ becomes higher than the reference voltage Vref can be latched by the first register 1265a. The detection count Tout_c will be identified as a resistive defect by the decision circuit 1267. Therefore, the decision circuit 1267 will output the bonding defect detection result BDDR as the resistive defect.

At the point in time T1, the precharge section tPRCH of the word line WLi ends, and at the same time, the reset section tRST starts. The third enable signal En3 in the reset section tRST transitions from a low level to a high level. Then, the lowered word line voltage VWL′ is initialized to the development start voltage Vds. Here, the development start voltage Vds must be higher than the reference voltage Vref. In addition, the counter 1263 also initializes the count value CNT.

At time T2, the development section tDEV of the word line WLi starts. The test controller 1245 transitions the first enable signal En1 to a low level to turn off the first power switch PSW1. Then, the supply of the word line voltage VWL to the word line WLi is stopped, and the development of the precharged word line WLi occurs. In addition, as the third enable signal En3 is deactivated, the development of the lowered word line voltage VWL′ starts from the initialized development start voltage Vds. At the same time, the counting operation of the initialized counter 1263 starts according to the activation of the second enable signal En2.

In the development section tDEV, the comparator 1261 transitions the comparison result Vout to the low level at the moment when the lowered word line voltage VWL′ becomes lower than the reference voltage Vref. That is, when there is a leakage as in the curve C4, the lowered word line voltage VWL′ becomes lower than the reference voltage Vref. At this point, the second register 1265b latches the detection count Tout2. The detection count Tout2 is compared with the third reference value Tref3 by the third comparator 1267c of the decision circuit 1267. If the detection count Tout2 is less than the third reference value Tref3, the third comparator 1267c will determine that there is the short defect. On the other hand, if the detection count Tout2 is not output during the development maximum count M_dev or is greater than the third reference value Tref3, the third comparator 1267c will determine that there is no short defect.

At time T4, the development section tDEV ends. At this time, the test controller 1245 deactivates the first enable signal En1 and the second enable signal En2 to the low level and activates the third enable signal En3 to the high level. Then, the counter 1263 is initialized.

In the above, the defect detection operation using the lowered word line voltage VWL′ of the bonding defect detector 1260′ has been described. The bonding defect test operation using the lowered word line voltage VWL′ using the voltage drop circuit 1262 enables operation of the bonding defect detector 1260′ in a low voltage environment. Accordingly, all type of the open defect, the resistive defect, and the short defects of word line bonding can be detected through one word line WLi precharge.

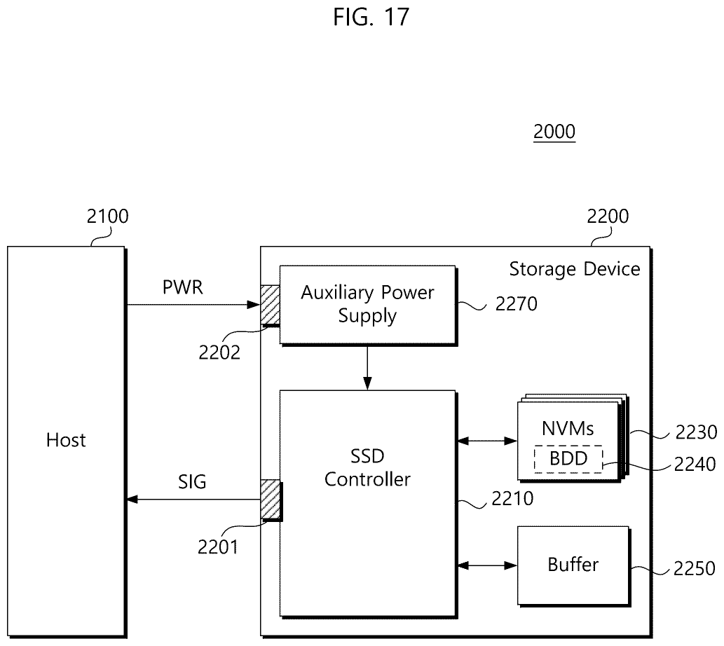

FIG. 17 is a block diagram showing a storage system including a non-volatile memory device according to an embodiment. Referring to FIG. 17, a storage system 2000 includes a host 2100 and a storage device 2200 implemented as a solid state drive. In an example embodiment, the storage device 2200 may include a plurality of non-volatile memory devices 2230 described with reference to FIGS. 1 to 16.

The storage device 2200 exchanges a signal SIG with the host 2100 through a signal connector 2201 and receives power PWR through a power connector 2202. The storage device 2200 includes an SSD controller 2210, a plurality of non-volatile memories 2230, a buffer memory 2250, and an auxiliary power supply 2270.

The SSD controller 2210 can control a plurality of non-volatile memories 2230 in response to the signal SIG received from the host 2100. The plurality of non-volatile memories 2230 can operate under the control of the SSD controller 2210. The auxiliary power supply 2270 is connected to the host 2100 through the power connector 2202. The auxiliary power supply 2270 can receive power PWR from the host 2100 and charge it. The auxiliary power supply 2270 can provide power to the storage device 2200 when the power supply from the host 2100 is not smooth. The buffer memory 2250 can be used as a buffer memory of the storage device 2200.

In an example embodiment, each of the plurality of non-volatile memories 2230 can include a bonding defect detector 2240. Each of the plurality of non-volatile memories 2230 can identify the presence or absence of a defect in word line bonding WLB and the type of defect through the bonding defect detector 2240. In particular, all type of an open defect, a resistive defect, and a short defect can be detected by the bonding defect detector 2240.

The above-described specific embodiments are examples. The above-described embodiments may include various design changes or changeable embodiments. Various techniques that can be used to modify and implement the embodiments. Therefore, the scope of the present disclosure is not be limited to the above-described embodiments, and should be defined by the claims and equivalents of the claims.

What is claimed is:

1. A non-volatile memory device comprising:
a cell array comprising memory cells connected to a word line;
a voltage generator configured to generate a word line voltage and provide the word line voltage to the word line;
a word line bonding configured to electrically connect the voltage generator and the word line; and
a bonding defect detection circuit connected to a first node between the voltage generator and the word line bonding, and configured to detect a voltage level of the first node in a precharge section of the word line or in a development section of the word line to determine whether there is a defect in the word line bonding,
wherein the bonding defect detection circuit is further configured to:
detect a precharge speed of the word line in the precharge section to identify an open defect or a resistive defect, and
detect a discharge speed of the word line that has been precharged in the development section to identify a short defect in the word line bonding.

2. The non-volatile memory device of claim 1, wherein the bonding defect detection circuit comprises:
a comparator configured to compare the voltage level of the first node with a reference voltage;
a counter configured to perform a counting operation based on a first enable signal and reset based on a second enable signal;
a register configured to latch a count output of the counter based on an output of the comparator and output the count output as a detection count; and
a decision circuit configured to determine a defect type of the word line bonding based on the detection count.

3. The non-volatile memory device of claim 2, wherein the register is configured to:
latch the count output based on the voltage level of the first node becoming higher than the reference voltage in the precharge section, and
latch the count output based on the voltage level of the first node becoming lower than the reference voltage in the development section.

4. The non-volatile memory device of claim 2, wherein the decision circuit is further configured to determine that the defect is the open defect based on the detection count being less than a first reference value in the precharge section.

5. The non-volatile memory device of claim 4, wherein the decision circuit is further configured to determine that the defect is the resistive defect based on the detection count being greater than a second reference value higher than the first reference value in the precharge section.

6. The non-volatile memory device of claim 5, wherein the decision circuit is further configured to determine a result is normal based on the detection count being greater than the first reference value and less than the second reference value in the precharge section.

7. The non-volatile memory device of claim 6, wherein the decision circuit is further configured to determine that the defect is the short defect based on the detection count being less than a third reference value in the development section.

8. The non-volatile memory device of claim 2, further comprising:
a power switch configured to transmit the word line voltage to the first node based on a third enable signal.

9. The non-volatile memory device of claim 8, further comprising,
a test controller configured to generate the first enable signal, the second enable signal, and the third enable signal,
wherein the test controller is further configured to activate the second enable signal so that the counter is reset when a precharge section ends.

10. A method of detecting bonding defect a non-volatile memory device that transmits a word line voltage generated by a voltage generator to a word line of a cell array through a word line bonding, the method comprising:
precharging the word line with the word line voltage;
counting a first time when a voltage level of the word line becomes higher than a reference voltage from a time of precharge using a counter to generate a first detection count; and
identifying a bonding defect of the word line based on the first detection count,
wherein the bonding defect is an open defect or a resistive defect.

11. The method of claim 10, wherein the identifying the bonding defect comprises, based on the first detection count being less than a first reference value, identifying the bonding defect as the open defect.

12. The method of claim 11, wherein the identifying the bonding defect further comprises, based on the first detection count being greater than or equal to the first reference value and being less than or equal to a second reference value, identifying the bonding defect does not exist.

13. The method of claim 12, wherein the identifying the bonding defect further comprises, based on the first detection count being greater than or equal to the second reference value, identifying the bonding defect as the resistive defect.

14. The method of claim 10, further comprising:
resetting the counter;
electrically separating the word line precharged with the word line voltage from the voltage generator;
counting a second time when a development level of the word line becomes lower than the reference voltage to generate a second detection count; and
identifying the bonding defect of the word line based on the second detection count,
wherein the bonding defect identified based on the second detection count is a short defect.

15. The method of claim 14, wherein the short defect does not exist when the development level of the word line becoming lower than the reference voltage does not occur.

16. A non-volatile memory device comprising:
memory cells connected to a word line;
a voltage generator configured to generate a word line voltage and provide the word line voltage to the word line;
a word line bonding configured to electrically connect the voltage generator and the word line;
a voltage drop circuit connected to a first node between the voltage generator and the word line bonding to drop a level of the word line voltage and provide a dropped word line voltage as a detection voltage to a second node; and
a bonding defect detection circuit configured to detect a level of the detection voltage in a precharge section of the word line or in a development section of the word line to determine whether the word line bonding is defective,
wherein the bonding defect detection circuit is further configured to:
detect a precharge speed of the word line in the precharge section based on the level of the detection voltage to identify an open defect or a resistive defect, and
detect a discharge speed of the word line that has been precharged in the development section to identify a short defect of the word line bonding.

17. The non-volatile memory device of claim 16, wherein the bonding defect detection circuit comprises:
a comparator configured to compare the detection voltage with a reference voltage;
a counter performing a counting operation based on a first enable signal and reset based on a second enable signal;
a first register configured to latch a count output of the counter based on an output of the comparator at a first time point when the detection voltage becomes higher than the reference voltage in the precharge section, and provide the count output as a first detection count;
a second register configured to latch the count output of the counter based on the output of the comparator at a second time point when the detection voltage becomes lower than the reference voltage in the development section, and provide the count output as a second detection count; and
a decision circuit configured to compare the first detection count or the second detection count with a reference value to determine a type of defect in the word line bonding.

18. The non-volatile memory device of claim 17, further comprising:
a first power switch configured to transmit the word line voltage to the first node based on a third enable signal.

19. The non-volatile memory device of claim 18, further comprising:
a second power switch configured to initialize the second node to a development start voltage based on the second enable signal when a precharge section ends.

20. The non-volatile memory device of claim 19, further comprising:
a programmable E-fuse configured to provide the reference value to the decision circuit.
